(19) United States
(12) Patent Application Publication
(10) Pub. No.: US 2009/0125784 A1
(43) Pub. Date: May 14, 2009

(54) MEMORY SYSTEM

(76) Inventor: Takashi OSHIMA, Chiba-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/270,343

(22) Filed: Nov. 13, 2008

(30) Foreign Application Priority Data
Nov. 14, 2007 (JP) 2007-295486

(51) Int. Cl. G06F 12/00; H03M 13/05; G06F 11/08

(52) U.S. Cl. 714/763; 711/154; 714/E11.03; 711/E12.001

(57) ABSTRACT

A memory system has a plurality of operation modes corresponding to current drawn and accessibility. The system includes a nonvolatile memory which stores a transition log of an operation mode, and a controller which, whenever accessing a predetermined amount of data of the nonvolatile memory in the same operation mode, adds the operation mode to the transition log, and determines a present operation mode by using the transition log.

### CROSS-REFERENCE TO RELATED APPLICATIONS

This application is based upon and claims the benefit of priority from prior Japanese Patent Application No. 2007-295486, filed Nov. 14, 2007, the entire contents of which are incorporated herein by reference.

### BACKGROUND OF THE INVENTION

1. Field of the Invention

The present invention relates to a memory system, e.g., a memory system including a nonvolatile memory such as a NAND flash memory.

2. Description of the Related Art

A memory system (e.g., a memory card) including a nonvolatile semiconductor memory and a controller for controlling the memory is known. The memory card is connected to a host apparatus, and stores data or outputs stored data in accordance with a request from the host apparatus. Also, the memory card operates by receiving power supply from the host apparatus. The power from the host apparatus is supplied to the controller and memory of the memory card.

For the convenience of users, apparatuses having various forms and features exist as the host apparatus. Examples are a digital camera, printer, Universal Serial Bus (USB) memory, personal computer (PC), and card reader/writer. Various makers manufacture these various forms of host apparatuses.

User's demands for increasing the speeds of memory card operations (e.g., data write and read) are always increasing. To meet these demands for high speeds, various techniques have been proposed and put to practical use. These techniques generally draw currents larger than those drawn by normal operations. The current drawn changes depending on speed-up techniques. Thus, the current drawn by the memory card tends to rise.

The host apparatus is required to be able to apply a voltage determined by the standards to the memory card. If the memory card draws a large current, however, some host apparatuses cannot apply the prescribed voltage owing to, e.g., the design of a power supply circuit. If the applied voltage is lower than the prescribed value, the memory card may cause an operation error. The strength of the power supply of the host apparatus against the current drawn depends on the host apparatus. Against a certain current drawn, therefore, some host apparatuses can apply the prescribed voltage, whereas others cannot.

To support a host apparatus having a low-strength power supply, it is possible to uniformly reduce the current drawn by memory cards. However, this method makes a memory card unable to achieve its possible performance. The method also suppresses the performance of a host apparatus having a high power supply ability and capable of high-speed access to a memory card.

As a relevant technique of this kind, the following reference has disclosed a technique for preventing the decrease in write speed in a semiconductor memory device including a plurality of planes.

Jpn. Pat. Appln. KOKAI Publication No. 2007-199905

### BRIEF SUMMARY OF THE INVENTION

According to an aspect of the present invention, there is provided a memory system having a plurality of operation modes corresponding to current drawn and accessibility, the system comprising: a nonvolatile memory which stores a transition log of an operation mode; and a controller which, whenever accessing a predetermined amount of data of the nonvolatile memory in the same operation mode, adds the operation mode to the transition log, and determines a present operation mode by using the transition log.

### BRIEF DESCRIPTION OF THE SEVERAL VIEWS OF THE DRAWING

FIG. 1 is a block diagram showing the arrangement of a memory card 1 according to an embodiment of the present invention;

FIG. 2 is a view showing signals allocated to signal pins 13;

FIG. 3 is a block diagram showing the arrangement of a controller 12;

FIG. 4 is a block diagram showing the arrangement of a NAND flash memory 11-1;

FIG. 5 is a view showing the arrangement of a memory area 30 of a NAND flash memory 11;

FIG. 6 is a schematic view showing the arrangement of one data block included in the NAND flash memory 11;

FIG. 7 is a schematic view showing the arrangement of a central management block included in the NAND flash memory 11;

FIG. 8 is a flowchart showing the operation of the memory card 1; and

FIG. 9 is a flowchart showing the operation of the memory card 1 following FIG. 8.

### DETAILED DESCRIPTION OF THE INVENTION

An embodiment of the present invention will be explained below with reference to the accompanying drawing. Note that in the following explanation, the same reference numbers denote elements having the same functions and arrangements, and a repetitive explanation will be made only when necessary.

This embodiment will be explained by taking a memory card as an example of a memory system. The memory card is designed to be detachable from a host apparatus. However, the present invention is not limited to the memory card, and the memory system and host apparatus may also be formed as one large-scale integrated circuit (LSI). That is, a controller and nonvolatile semiconductor memory forming the memory system may also be mounted on a printed circuit board on which the host apparatus is mounted.

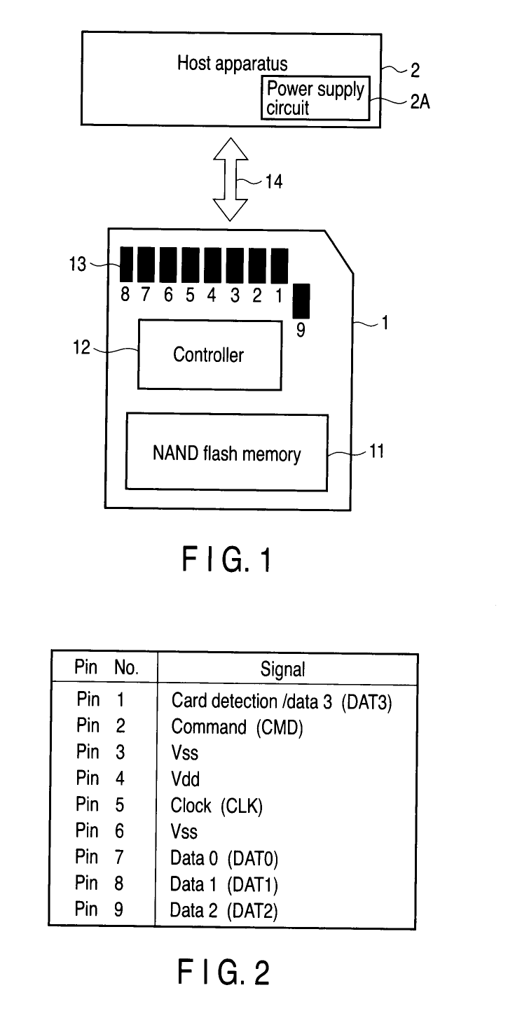

FIG. 1 is a block diagram showing the configuration of a memory system (memory card) 1 according to the embodiment of the present invention. When connected to a host apparatus 2, the memory card 1 operates by receiving power supply, and performs an access process corresponding to a request from the host apparatus 2. The host apparatus 2 comprises hardware and software for accessing the memory card 1 connected via a bus interface 14. The host apparatus 2 also comprises a power supply circuit 2A for supplying power to the memory card 1.

The memory card 1 exchanges data with the host apparatus 2 via the bus interface 14. The memory card 1 comprises a NAND flash memory 11 as a kind of a nonvolatile memory, a controller 12 for controlling the NAND flash memory 11, and signal pins (first to ninth pins) 13. Note that the nonvolatile memory is not limited to the NAND flash memory 11, and various types of nonvolatile memories can be used.

The signal pins 13 are electrically connected to the controller 12. FIG. 2 shows an example of signal allocation to the first to ninth pins included in the signal pins 13. FIG. 2 is a view showing the relationship between the first to ninth pins included in the signal pins 13, and signals allocated to these pins.

Data 0, data 1, data 2, and data 3 are respectively allocated to the seventh, eighth, ninth, and first pins. The first pin is also allocated to a card detection signal. The second pin is allocated to a command CMD. The third and sixth pins are allocated to a ground voltage Vss. The fourth pin is allocated to a power supply voltage Vdd. The fifth pin is allocated to a clock signal CLK. The power supply circuit 2A of the host apparatus 2 applies the power supply voltage Vdd and ground voltage Vss.

The memory card 1 can be inserted into a slot formed in the host apparatus 2. A host controller (not shown) of the host apparatus 2 communicates various signals and data with the controller 12 in the memory card 1 via the first to ninth pins.

When writing data in the memory card 1, for example, the host controller sends a write command as a serial signal to the controller 12 via the second pin. The controller 12 receives the write command input to the second pin by using the clock signal CLK supplied to the fifth pin. After that, the host controller sends write data to the controller 12 via the seventh, eighth, ninth, and first pins. The host controller in the host apparatus 2 and the memory card 1 thus communicate with each other by using the signal pins 13 and the bus interface 14 corresponding to them.

By contrast, the NAND flash memory 11 and controller 12 communicate with each other by using a NAND flash memory interface. Although not shown, therefore, the NAND flash memory 11 and controller 12 are connected by, e.g., 8-bit input/output (I/O) lines.

When writing data in the NAND flash memory 11, for example, the controller 12 sequentially inputs a data input command 80H, column address, page address, data, and program command 10H to the NAND flash memory 11 via these I/O lines. “H” of the command 80H indicates a hexadecimal number. In practice, 8-bit signals “10000000” are supplied parallel to the 8-bit I/O lines. That is, in this NAND flash memory interface, a plurality of bits of a command are supplied parallel.

Also, in the NAND flash memory interface, commands and data for the NAND flash memory 11 are communicated by using the same I/O lines. Thus, the interface by which the host controller in the host apparatus 2 and the memory card 1 communicate with each other differs from the interface by which the NAND flash memory 11 and controller 12 communicate with each other.

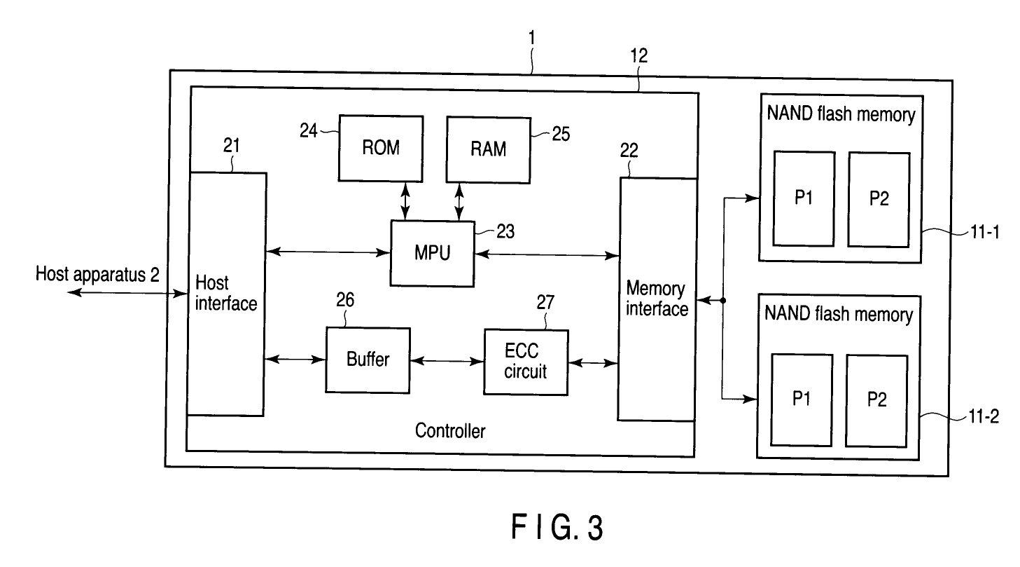

The internal arrangement of the controller 12 of the memory card 1 shown in FIG. 1 will be explained below. FIG. 3 is a block diagram showing the arrangement of the controller 12.

The controller 12 manages the physical state (e.g., which physical block address contains what number of logical sector address data, or which block is in an erased state) inside the NAND flash memory 11. The controller 12 comprises a host interface circuit (host interface) 21, memory interface circuit (memory interface) 22, microprocessing unit (MPU) 23, read-only memory (ROM) 24, random access memory (RAM) 25, buffer 26, and error check and correction (ECC) circuit 27.

The host interface circuit 21 interfaces the controller 12 with the host apparatus 2.

The MPU 23 controls the overall operation of the memory card 1. When the memory card 1 receives power supply, for example, the MPU 23 reads firmware (a control program) stored in the ROM 24 onto the RAM 25 and executes predetermined processing, thereby forming various tables on the RAM 25. Also, the MPU 23 receives a write command, read command, erase command, and the like from the host apparatus 2, and executes predetermined processing on the NAND flash memory 11, or controls data transfer by using the buffer 26.

The ROM 24 stores, e.g., the control program to be controlled by the MPU 23. The RAM 25 is used as a work area of the MPU 23, and stores the control program loaded from the ROM 24 and various tables. The memory interface circuit 22 interfaces the controller 12 with the NAND flash memory 11.

The buffer 26 temporality stores a predetermined amount of data based on the host interface when writing data transmitted from the host apparatus 2 into the NAND flash memory 11, or temporarily stores a predetermined amount of data when transmitting data read from the NAND flash memory 11 to the host apparatus 2.

For write data transmitted from the host apparatus 2, the ECC circuit 27 generates an error correction code for each data portion containing a predetermined number of bits. The NAND flash memory 11 stores each error correction code together with a data portion corresponding to the code. For read data transmitted from the NAND flash memory 11, the ECC circuit 27 detects and corrects an error in each data portion by using the error correction code. After this error correction, the ECC circuit 27 supplies the data from which the error correction codes are removed to the buffer 26. Accordingly, the memory card 1 transmits read data containing no error correction code to the host apparatus 2.

The memory card 1 comprises a plurality of NAND flash memories 11. In this embodiment, FIG. 3 shows two NAND flash memories 11-1 and 11-2 as an example. However, the number of the NAND flash memories 11 may of course be three or more. In the following explanation, these NAND flash memories will be collectively described as the NAND flash memories 11 if it is unnecessary to distinguish between them.

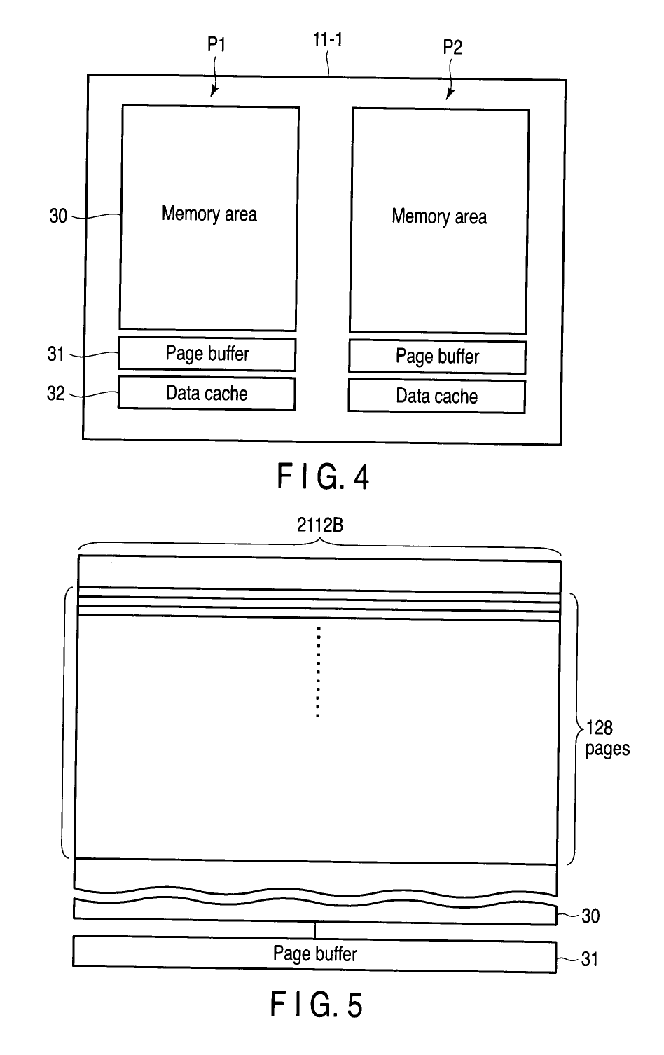

To make high-speed access feasible, each NAND flash memory 11 comprises a plurality of planes. In this embodiment, FIG. 3 shows two planes P1 and P2 as an example. However, the number of the planes P may naturally be three or more. FIG. 4 is a block diagram showing the arrangement of the NAND flash memory 11-1. The NAND flash memory 11-2 has the same arrangement as that shown in FIG. 4.

Each plane P includes a memory area 30 as a memory cell array, a data cache 32 for exchanging data with the memory interface circuit 22, and a page buffer 31 for holding data from the memory area 30 or data cache 32. The memory area 30 comprises a plurality of blocks as data erase units. Each block contains a plurality of pages as data write units (or data read units).

By using the two buffers, i.e., the data cache 32 and page buffer 31, each plane P can write data of the page buffer 31 to the memory area 30 while the controller 12 is reading data form the data cache 32.

Each block comprises a plurality of NAND strings arranged in order along the row direction. Each NAND string has two selection transistors, and a plurality of memory cell transistors connected in series between these selection transistors.

Each memory cell transistor is a metal oxide semiconductor field-effect transistor (MOSFET) having a stacked gate structure formed on a semiconductor substrate. The stacked gate structure includes a charge storage layer (floating gate electrode) formed on a gate insulating film on the semiconductor substrate, and a control gate electrode formed on an inter-gate insulating film on the charge storage layer. Each memory cell transistor changes its threshold voltage in accordance with the number of electrons stored in the floating gate electrode, and stores data in accordance with the change in threshold voltage.

The control gate electrodes of a plurality of memory cell transistors arranged in the same row in each block are connected to the same word line. The plurality of memory cell transistors connected to the same word line are processed as a page, and data write and read are performed page by page. Also, data is erased for every block containing a plurality of pages.

FIG. 5 is a view showing the arrangement of the memory area 30 of the NAND flash memory 11. As described previously, the memory area 30 comprises a plurality of blocks each containing a plurality of pages.

Each page has, e.g., 2,112 bytes (B) (512−B data area×4+10−B ECC area×4+24−B management data area). For example, 128 pages form a block (256 KB+8 KB [K is 1,024]) as a data erase unit. In this embodiment, therefore, the storage capacity of the page buffer 31 is 2,112 B (2,048 B+64 B) corresponding to the data size of one page.

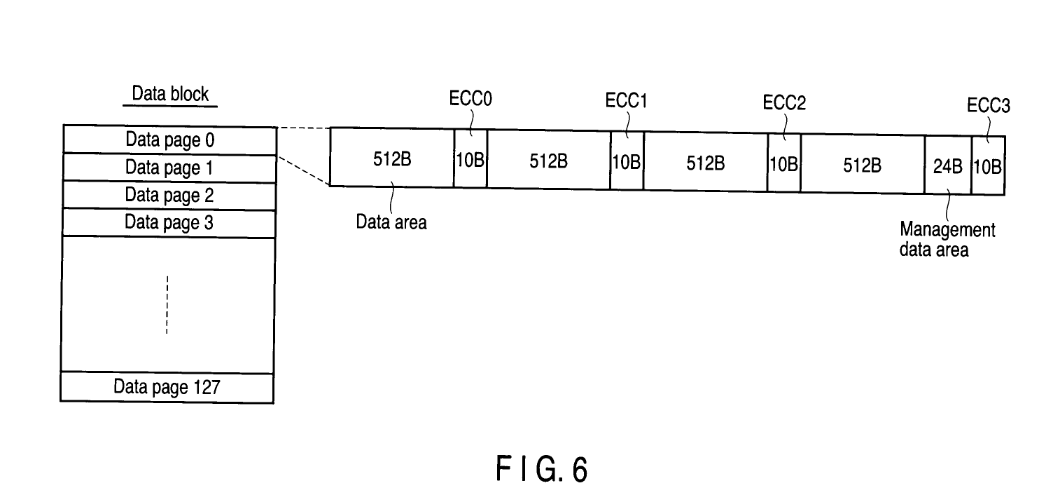

The NAND flash memory 11 has a data block and central management block. A plurality of data blocks exist in the NAND flash memory 11, and are used to store user data (data such as documents, still images, and motion images that the user can read and write). FIG. 6 is a schematic view showing the arrangement of one data block included in the NAND flash memory 11.

Each data block contains 128 data pages 0 to 127. Each data page has four data areas each of which stores 512-byte data, and four 10-byte ECC areas storing four error correction codes (ECC0 to ECC3) corresponding to the four data areas. Also, a 24-byte management data area is formed after the last data area (fourth data area) in the data page. Accordingly, the last ECC area (fourth ECC area) in the data page corresponds to both the fourth data area and management data area. The management data area stores management data containing, e.g., a logical block address and physical block address.

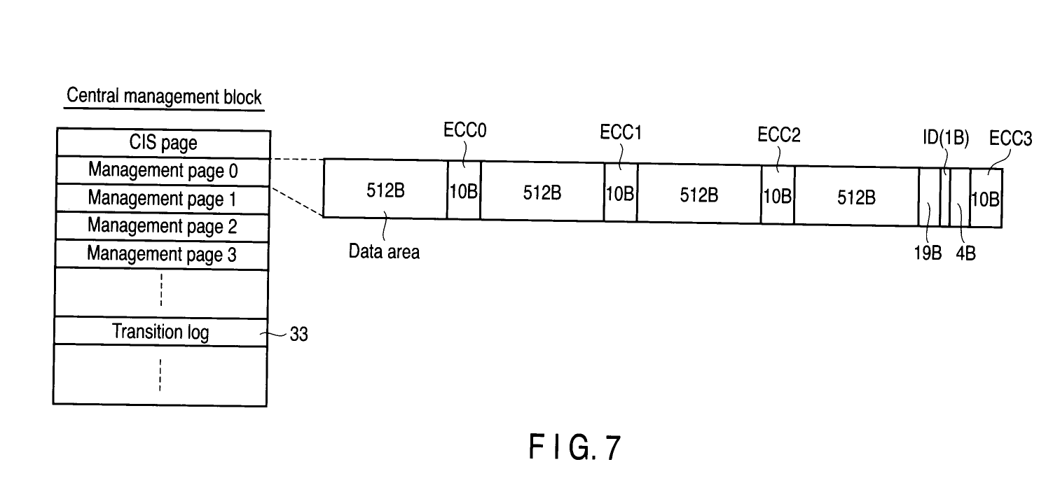

FIG. 7 is a schematic view showing the arrangement of the central management block included in the NAND flash memory 11. Only one central management block is formed in the NAND flash memory 11 (i.e., in one of the NAND flash memories 11-1 and 11-2).

The central management block contains one card information structure (CIS) page and a plurality of management pages (management pages 0, 1, 2, 3, . . . ). This central management block is a special block that collectively stores various kinds of management information pertaining to the NAND flash memory 11. The user is basically unable to freely read or write this management information. The host apparatus 2 or controller 12 uses the management information when, e.g., the NAND flash memory 11 is activated.

The CIS page in the central management block is used to check, e.g., whether the NAND flash memory 11 is formatted in accordance with the physical format specifications of a predetermined memory card.

Each management page in the central management block stores management information indicating whether each data block is a bad block having an error, indicating whether each data block is a free block, or indicating the logical block address of written data. The management page further stores a transition log 33 of operation modes (to be described later), and the physical address of an erased data block from which data write is started.

Each management page includes four data areas each of which stores 512-byte management data, and four 10-byte ECC areas storing four error correction codes (ECC0 to ECC3) corresponding to the four data areas. A 1-byte ID area is an area for storing the type of data written in the management page and the bad block attribute. Areas “19 B” and “4 B” are free areas (unused areas). Therefore, the last ECC area (fourth ECC area) in the management page corresponds to both the fourth data area and ID area.

To achieve a high-speed access process (i.e., a high data transfer rate) by the memory card 1, the controller 12 (MPU 23) is designed to implement various methods of access (data write and read) to the NAND flash memory 11.

Various methods of access from the controller 12 to the NAND flash memory 11 presently exist, and are expected to be created in the future as well. Therefore, not all these methods can be mentioned in this embodiment, so some examples will be explained below. However, the scope of the present invention is not limited to the access method itself, and includes cases using access methods to be proposed in the future. This embodiment defines three operation modes M1 to M3 below as examples.

Operation mode M1 is a so-called “2-chip simultaneous access enabled” operation mode in which it is possible to simultaneously access the two NAND flash memories (chips) 11-1 and 11-2. That is, in operation mode M1, data write or read is performed on the two NAND flash memories 11-1 and 11-2 at the same time.

Operation mode M2 is a so-called “2-chip simultaneous access disabled and 2-plane simultaneous access enabled” operation mode in which it is possible to access only one of the two NAND flash memories 11-1 and 11-2 and simultaneously access the two planes P1 and P2. That is, in operation mode M2, data write or read can be performed on the two planes P1 and P2 of one NAND flash memory 11 at the same time.

Operation mode M3 is a “2-chip simultaneous access disabled and 2-plane simultaneous access disabled” operation mode in which it is possible to access only one of the two NAND flash memories 11-1 and 11-2 and only one of the two planes P1 and P2. That is, in operation mode M3, data write or read is performed on only one plane of one NAND flash memory 11.

The accessibility (data transfer rate) of operation mode M1 is highest, and the accessibility decreases in the order of operation modes M2 and M3. Also, the current drawn is proportional to the accessibility; the current drawn in operation mode M1 is largest, and the current drawn decreases in the order of operation modes M2 and M3.

The operation of the memory card 1 having the above arrangement will be explained below.

Assume that in the initial state (when shipped from the factory), the memory card 1 is set in operation mode M3 in which the current drawn is smallest (the accessibility is lowest). That is, in this initial state, M3 is written as an operation mode to the transition log 33 contained in the central management block in the NAND flash memory 11.

Also, when starting data write in an erased data block of the NAND flash memory 11, the controller 12 writes the physical address of the data block to the central management block. When the memory card 1 is activated, therefore, the controller 12 can search for a data block in which data is written last, by checking the management information of the central management block.

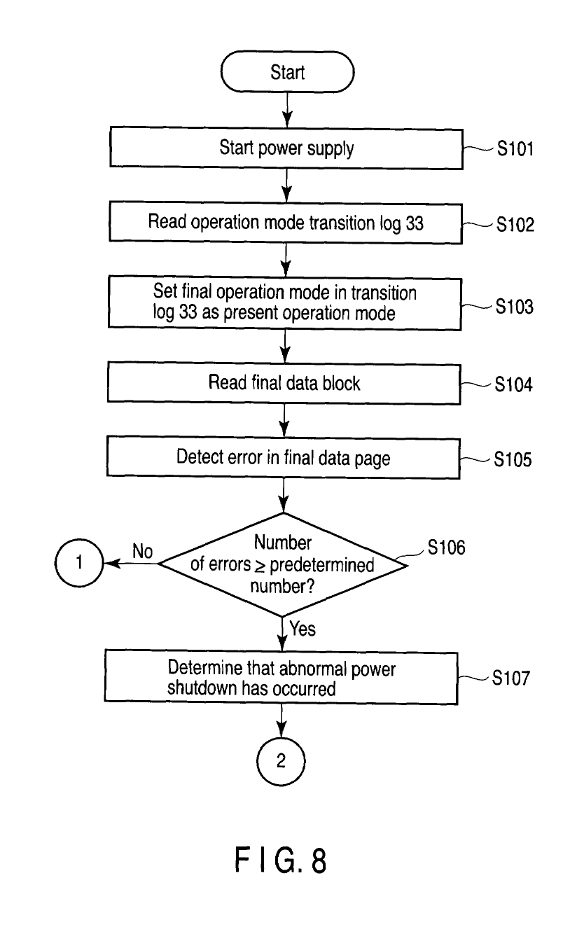

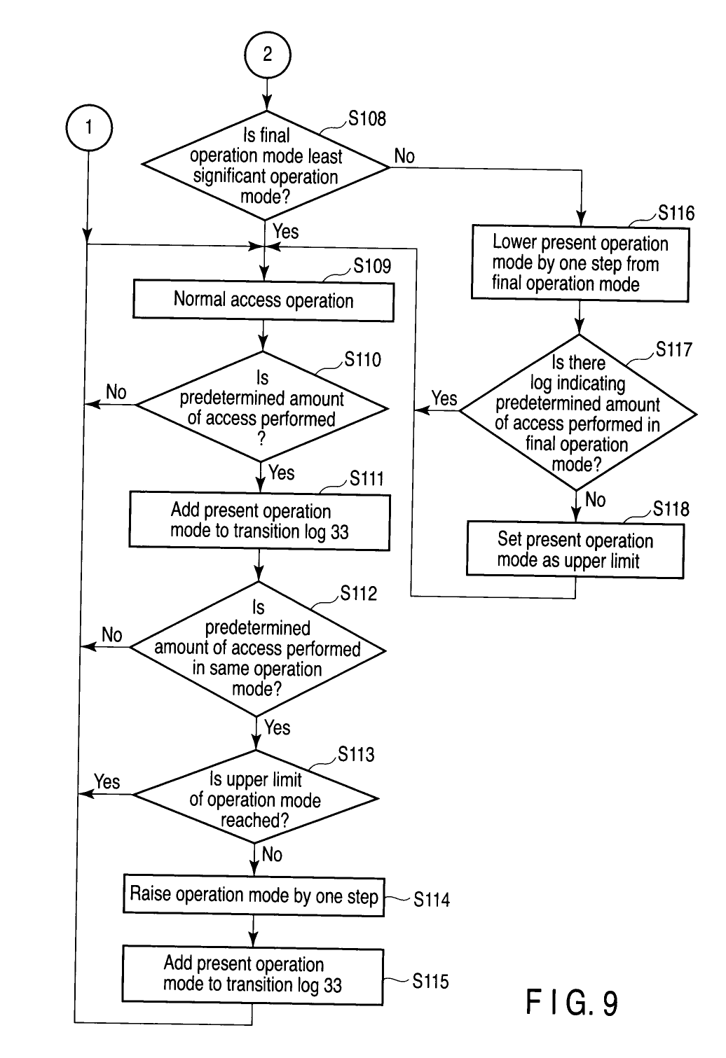

FIGS. 8 and 9 are flowcharts showing the operation of the memory card 1. First, the memory card 1 is activated when the host apparatus 2 starts supplying power to the memory card 1 (step S101). Upon receiving this power supply, the controller 12 reads the transition log 33 (of the operation mode) contained in the central management block from the NAND flash memory 11 (step S102). The read transition log 33 is stored in, e.g., the RAM 25.

Subsequently, the controller 12 sets a lastly added operation mode (final operation mode) contained in the transition log 33 as a present operation mode (step S103). The controller 12 then acquires the physical address of a data block (final data block) in which data is written last from the central management block, and reads all data of the final data block from the NAND flash memory 11 by using the physical address (step S104). The data is stored in, e.g., the RAM 25.

The controller 12 detects a data page (final data page) in which data is written last, from a plurality of data pages contained in the final data block. Subsequently, the ECC circuit 27 detects errors in the final data page under the control of the controller 12 (step S105). The ECC circuit 27 then checks whether the number of errors in the final data page is greater than or equal to a predetermined number (step S106).

If it is determined in step S106 that the number of errors is greater than or equal to the predetermined number, the controller 12 determines that abnormal power shutdown has occurred in the last activation (e.g., power shutdown has occurred during data write) (step S107). Examples of the cause of this abnormal power shutdown are the case where the current drawn by the memory card 1 increases to make the power supply circuit 2A of the host apparatus 2 unable to supply a corresponding current, and the case where the current drawn by the memory card 1 increases to make the voltage much lower than the voltage determined by the standards of the memory card 1.

Note that the ECC circuit 27 generates one error correction code for every 512-byte data. That is, the calculation unit of the ECC circuit 27 is 512 bytes (or partly 536 bytes), and four calculation units exist in one data page. Accordingly, the upper limit of the number of errors is four. If a predetermined number or more of the four errors are errors (i.e., if a predetermined number or more of four 512-byte data have uncorrectable errors), the controller 12 determines that abnormal power shutdown has occurred in the last activation. This predetermined number is used to distinguish between a simple bit defect and abnormal power shutdown, and can be freely set because it changes in accordance with, e.g., the correction capability of the ECC. In this embodiment, the controller 12 determines that abnormal power shutdown has occurred if all the four 512-byte data have uncorrectable errors (if the predetermined number is four).

On the other hand, if it is determined in step S106 that the number of errors is less than the predetermined number, the controller 12 determines that the last power shutdown is normal power shutdown. Note that the normal power shutdown is, e.g., the case where the host apparatus 2 has shut down the power by normal steps in accordance with user's instructions. In this case, a normal program terminating process is executed on the memory card 1. The controller 12 advances to step S109 to execute a normal access operation (e.g., a data write or read operation).

Subsequently, the controller 12 checks whether the final operation mode contained in the transition log 33 is the least significant operation mode (in this embodiment, operation mode M3) (step S108). If it is determined in step S108 that the final operation mode is the least significant operation mode, the controller 12 executes the normal access operation (step S109). The controller 12 keeps executing the normal access operation until a predetermined amount of access is performed (step S110).

Note that a predetermined amount of access indicates that the controller 12 performs a write or read operation of a predetermined amount of data on the NAND flash memory 11. Note also that the write operation of a predetermined amount of data indicates a data write operation performed a plurality of times (e.g., twice in this embodiment) corresponding to a plurality of commands (e.g., write commands). Similarly, the read operation of a predetermined amount of data indicates a data read operation performed a plurality of times corresponding to a plurality of commands (e.g., read commands). A predetermined amount of access to be described below also indicates the above operation.

If it is determined in step S110 that the predetermined amount of access is performed, the controller 12 adds the present operation mode to the transition log 33 (step S111). For example, if the access operation is performed in operation mode M3, operation mode M3 is added to the transition log 33 like “M3→M3”.

Then, the controller 12 executes the normal access operation until a predetermined amount of access is performed in the same operation mode (step S112). If it is determined in step S112 that the predetermined amount of access is performed, the controller 12 checks whether the upper limit of the operation mode set in step S118 (to be described later) is reached (step S113). If it is determined in step S113 that the upper limit of the operation mode is reached, the controller 12 returns to step S109 to execute the normal access operation.

On the other hand, if it is determined in step S113 that the upper limit of the operation mode is not reached, the controller 12 raises the present operation mode by one step (step S114). The controller 12 then adds the present operation mode, i.e., the operation mode raised by one step in step S114 to the transition log 33 (step S115). After that, the controller 12 returns to step S109 to execute the normal access operation. For example, if the operation mode is to be raised by one step when an access operation is performed twice in the same operation mode, the controller 12 adds operation mode M2 to the transition log 33 like “M3→M3→M2”, and performs an access operation in operation mode M2 after that.

If it is determined in step S108 that the final operation mode is not the least significant operation mode, the controller 12 lowers the present operation mode by one step from the final operation mode (step S116). That is, if the controller 12 detects abnormal power shutdown while the transition log 33 is “M1→M1”, the controller 12 performs an access operation in operation mode M2. This makes it possible to prevent the occurrence of abnormal power shutdown when power is supplied this time, by the same cause of abnormal power shutdown having occurred when power is supplied last time.

Subsequently, the controller 12 checks the transition log 33 to determine whether there is a log indicating that a predetermined amount of access is performed in the final operation mode when power is supplied last (step S117). That is, if the same operation mode is continuously performed twice or more, i.e., if the transition log 33 is “M1→M1→M1”, for example, the controller 12 determines that the predetermined amount of access is performed in the final operation mode.

If it is determined in step S117 that the predetermined amount of access is performed, the controller 12 returns to step S109 to execute the normal access operation, and executes steps S110 to S115 in order to further raise the operation mode.

On the other hand, if it is determined in step S117 that no predetermined amount of access is performed in the final operation mode, the controller 12 sets the present operation mode as the upper limit of the operation mode (step S118). For example, if the transition log 33 is “M3→M3→M2”, no predetermined amount of access is performed in final operation mode M2. This allows the controller 12 to determine that abnormal power shutdown has occurred after the operation mode is raised from M3 to M2. Accordingly, the host apparatus 2 currently being connected is fixed to the operation mode set as the upper limit. This makes it possible to prevent abnormal power shutdown of the host apparatus 2 after that. Then, the controller 12 returns to step S109 to execute the normal access operation, and repeats the normal access operation until the power supply is shut down (including both abnormal power shutdown and normal power shutdown).

As described above, if abnormal power shutdown is detected immediately after the operation mode is raised by one step while the transition log 33 is updated, the operation mode one step below the present operation mode is set as the upper limit. For example, if abnormal power shutdown is detected after the start of power supply and the transition log 33 at that time is “M3→M3→M2”, it is possible to determine that abnormal power shutdown has occurred immediately after the operation mode is raised from M3 to M2. Therefore, the upper limit of the operation mode is set to M3, and the operation mode for the host apparatus 2 is not raised from M3 after that.

In this embodiment as has been described in detail above, in the memory card 1 having a plurality of operation modes corresponding to the current drawn and accessibility, the operation mode transition log 33 is stored in the NAND flash memory 11 (more specifically, the central management block). If abnormal power shutdown has occurred in the last activation, the controller 12 switches the operation modes by using the operation mode transition log 33.

In this embodiment, therefore, an optimum operation mode (i.e., an operation mode capable of preventing abnormal power shutdown) can be selected for each host apparatus 2. Consequently, it is possible to prevent abnormal power shutdown and increase the access speed.

Also, since the ECC circuit 27 is used to detect abnormal power shutdown, the number of errors in a page in which data is written last is used as a determination criterion. This makes it possible to distinguish between a simple bit defect and abnormal power shutdown.

Furthermore, if unexpected power shutdown occurs for some accidental reason, the process (step S117) of raising the operation mode is performed. If unwanted power shutdown occurs for some incidental reason, therefore, it is possible to prevent the operation mode from being fixed to a low-speed operation mode.

Note that this embodiment has been explained by taking the case where the memory card 1 has a plurality of NAND flash memories as an example. However, it is of course also possible to apply this embodiment to the case where the memory card 1 has only one NAND flash memory. That is, even when this embodiment is applied to a memory card having a plurality of operation modes different in current drawn and accessibility for one NAND flash memory, an optimum operation mode can be selected for each host apparatus 2.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A memory system having a plurality of operation modes corresponding to current drawn and accessibility, the system comprising:
a nonvolatile memory which stores a transition log of an operation mode; and
a controller which, whenever accessing a predetermined amount of data of the nonvolatile memory in the same operation mode, adds the operation mode to the transition log, and determines a present operation mode by using the transition log.

2. The system according to claim 1, wherein whenever accessing a predetermined amount of data in the same operation mode, the controller switches to an operation mode having higher accessibility.

3. The system according to claim 1, wherein the controller determines whether abnormal power shutdown caused by an increase in current drawn has occurred, and, if the abnormal power shutdown is detected, executes a second operation mode in which the current drawn is smaller than that of a first operation mode used when the abnormal power shutdown has occurred.

4. The system according to claim 3, wherein
the nonvolatile memory includes a plurality of blocks as data erase units, each block including a plurality of pages as data write units, and
the controller determines that the abnormal power shutdown has occurred, if the number of errors in a page in which data is written last when power is supplied last is not less than a predetermined number.

5. The system according to claim 4, further comprising an ECC (error check and correction) circuit which generates an error correction code for each of a plurality of data portions forming each page, and corrects an error in the data portion by using the error correction code,
wherein the controller determines the number of errors on the basis of a result of error correction by the ECC circuit.

6. The system according to claim 3, wherein if no abnormal power shutdown is detected, the controller sets a final operation mode written in the transition log as the present operation mode.

7. The system according to claim 3, wherein the controller determines whether a predetermined amount of data is accessed in a final operation mode by using the transition log, and sets the second operation mode as an upper limit if the abnormal power shutdown is detected and no predetermined amount of data is accessed in the final operation mode.

8. The system according to claim 7, wherein the controller does not raise the present operation mode to any operation mode higher than the upper limit.

9. The system according to claim 1, wherein the nonvolatile memory includes a data area which stores user data, and a management area which stores the transition log.

10. The system according to claim 9, wherein
the nonvolatile memory includes a first memory unit and a second memory unit each having the data area, and
the management area is provided in one of the first memory unit and the second memory unit.

11. The system according to claim 10, wherein the controller is configured to simultaneously access the first memory unit and the second memory unit.

12. The system according to claim 1, wherein
the nonvolatile memory includes a first plane and a second plane each having a plurality of memory cells, and
the controller is configured to simultaneously access the first plane and the second plane.

13. The system according to claim 1, wherein the nonvolatile memory is a flash memory.
